(19) United States
(12) Patent Application Publication
(10) Pub. No.: US 2024/0413031 A1
(43) Pub. Date: Dec. 12, 2024

(54) ON DIE FLEXURE CONTROL DEVICE AND METHOD

(71) Applicant: Intel Corporation, Santa Clara, CA (US)

(72) Inventors: Chandru Periasamy, Portland, OR (US); Jagat Shakya, Hillsboro, OR (US); Joshua Jeremy Cardiel Rivera, Beaverton, OR (US); Jaime A. Sanchez, Beaverton, OR (US); Devesh Srivastava, Portland, OR (US); Feras Eid, Chandler, AZ (US); Matthew Zeman, Portland, OR (US); Xavier F. Brun, Chandler, AZ (US); Nabankur Deb, Beaverton, OR (US)

(21) Appl. No.: 18/207,808

(22) Filed: Jun. 9, 2023

(51) Int. Cl. H01L 23/31; H01L 21/56; H01L 23/367; H01L 23/373

(52) U.S. Cl. CPC H01L 23/3135; H01L 21/56; H01L 23/367; H01L 23/3735; H01L 22/14; H01L 23/29; H01L 23/291; H01L 23/293; H01L 24/16; H01L 24/17; H01L 24/32; H01L 24/33; H01L 24/73; H01L 2224/16145; H01L 2224/16225; H01L 2224/17181; H01L 2224/32145; H01L 2224/32225; H01L 2224/33181; H01L 2224/73204; H01L 2224/73253

(57) ABSTRACT

An electronic device and associated methods are disclosed. Electronic devices are shown that include a semiconductor die and a patterned layer connected to a backside of the die. Electronic devices are shown that include a pattern of elements across a patterned layer that varies across the backside of a die. Electronic devices are further shown that include a compliant filler within elements in a patterned layer.

### TECHNICAL FIELD

Embodiments described herein generally relate to semiconductor devices. More specifically, the present disclosure relates to techniques for mitigating die warpage.

### BACKGROUND

Semiconductor die cooling is a significant issue in electronic devices. Heat conducting and/or heat spreading materials are utilized to improve die cooling. Some heat conducting materials have different thermal coefficients of expansion (CTE). When laminated to a semiconductor die, differences in CTE may cause die warpage, which can lead to a number of technical issues.

It is desired to provide devices and methods that reduce or eliminate die warpage while also maintaining effective die cooling. Devices and methods are described that address these, and other technical challenges.

### BRIEF DESCRIPTION OF THE DRAWINGS

In the figures, which are not necessarily drawn to scale, like numerals may describe similar components in different views. Like numerals having different letter suffixes may represent different instances of similar components. The figures illustrate generally, by way of example, but not by way of limitation, various embodiments discussed in the present document.

FIG. 1 shows an isometric view of a semiconductor device in accordance with some example embodiments.

FIG. 2 shows a side view of a semiconductor device in accordance with some example embodiments.

FIG. 3 shows a side view of a semiconductor device in accordance with some example embodiments.

FIG. 4 shows a semiconductor device in accordance with some example embodiments.

FIG. 5 shows another semiconductor device in accordance with some example embodiments.

FIG. 6A shows a non-patterned layer of a semiconductor device in accordance with some example embodiments.

FIG. 6B shows a patterned layer of a semiconductor device in accordance with some example embodiments.

FIG. 6C shows another patterned layer of a semiconductor device in accordance with some example embodiments.

FIG. 7 shows a flow diagram of a method of manufacturing a semiconductor device in accordance with some example embodiments.

FIG. 8 shows a system that may incorporate an electronic device with a patterned layer and methods, in accordance with some example embodiments.

### DESCRIPTION OF EMBODIMENTS

The following description and the drawings sufficiently illustrate specific embodiments to enable those skilled in the art to practice them. Other embodiments may incorporate structural, logical, electrical, process, and other changes. Portions and features of some embodiments may be included in, or substituted for, those of other embodiments. Embodiments set forth in the claims encompass all available equivalents of those claims.

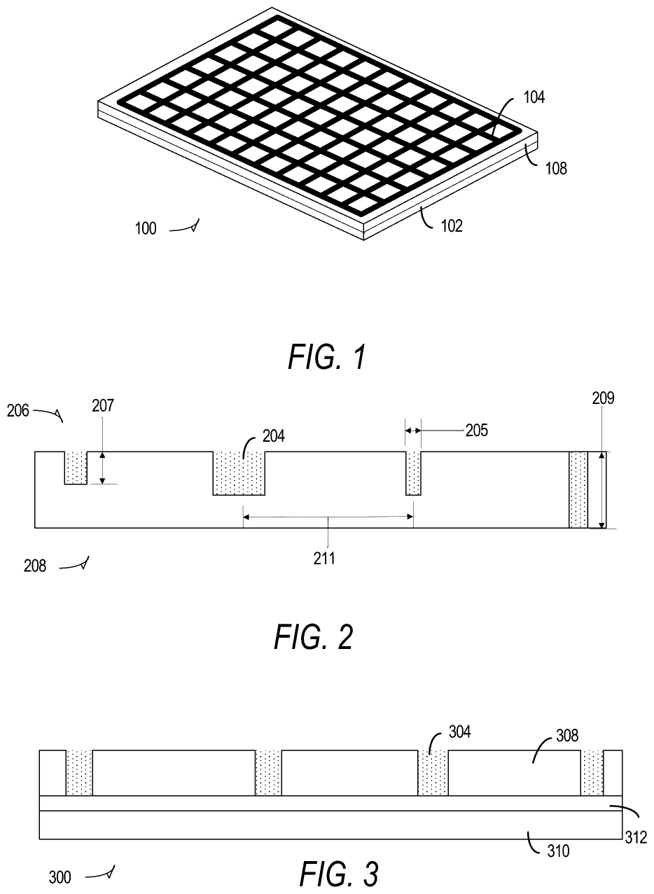

FIG. 1 shows a top view of a semiconductor device 100 in accordance with some example embodiments. The semiconductor device 100 includes a semiconductor die 102, such as a processor die, memory die, graphics die, controller die, etc. A patterned layer 108, is shown coupled to the die 102. In one example, the patterned layer 108 forms a direct interface with the die 102. A direct interface provides thermal conduction with a minimum distance for heat to travel. In one example, the patterned layer 108 is connected to the die 102 and includes one or more intervening layers between the die 102 and the patterned layer 108.

In one example, the patterned layer 108 is formed from a monolithic thermal conducting material such as a metal. In one example, the patterned layer 108 is formed from copper. Other materials for the patterned layer 108 include, but are not limited to, aluminum, silver, gold, nickel, diamond, aluminum nitride, Silicon carbide, or combinations of two or more of these materials, for example, a copper and diamond composite.

In one example, physical deposition techniques such as evaporation, sputtering, etc. are used to form the patterned layer 108 on the die 102. Other techniques of forming the patterned layer 108 are possible, including, but not limited to, chemical deposition, or laminating a separate sheet onto the die 102. Different techniques of forming will be detectable in an end product, for example, sputtering and evaporation will form a distinctive grain pattern in the bulk material as a result of the technique used. Other methods of formation will also be detectable in a final product, for example by cross sectioning and microscopic examination.

In the example of FIG. 1, the patterned layer 108 includes a pattern of elements 104 that form recesses in the patterned layer 108. In one example, the pattern of elements 104 include constant pitch in an X direction on the patterned layer 108. In one example, the pattern of elements 104 include constant pitch in an Y direction on the patterned layer 108. In one example, the pattern of elements 104 include constant pitch in both and X direction and a Y direction on the patterned layer 108. The pattern of elements 104 may vary across the backside of the die 110. Variation in the pattern of elements 104 can be used to adjust stresses in patterned layer 108 and improve or eliminate warpage due to thermal expansion coefficient differences in materials.

In one example, patterned layer 108 may consist of a thickness between 50 μm and 500 μm. The pattern of elements 104 may extend through an entire thickness of patterned layer 108 as shown in more detail in FIG. 2. The pattern of elements 104 may consist of straight lines that extend across the length and width of the backside of the die 110, as shown in FIG. 1. The pattern of elements 104 may consist of other forms or shapes, for example, angled lines, arc patterns or arc segments included in patterns, sinusoidal patterns, “wavy” patterns, triangular patterns, and others. The pattern of elements 104 may be formed by laser ablation. The pattern of elements 104 may be formed using a die-saw. Another method of forming the pattern of elements 104 includes, but is not limited to, etching, for example using lithographic techniques of masking.

FIG. 2 illustrates a side view of a patterned layer 208, similar to patterned layer 108 from FIG. 1. As shown in FIG. 2, the patterned layer 208 includes multiple recesses 206. In some embodiments, patterned layer 206 includes a pattern 206 made up of elements 204 that form recesses. Although the recesses 204 are shown with square bottoms, other forms of recesses are also within the scope of the invention, for example, triangular or rounded bottoms.

As noted above, in one example, the pattern 206 varies across the patterned layer 208. FIG. 2 shows three different widths 205. Depths 207 may also vary between individual elements 204 of the pattern 206. In one example a depth 209 extends across an entire thickness of patterned layer 208. In other embodiments, elements 204 may only extend across a portion of patterned layer 208. Variations and combinations of different widths 205, depths 207 pitch spacing 211, etc. can be used to tailor a thermal expansion effect within different X-Y locations in the patterned layer 208. These variations can mitigate or eliminate warpage due to thermal expansion coefficient differences in materials, such as between silicon and copper.

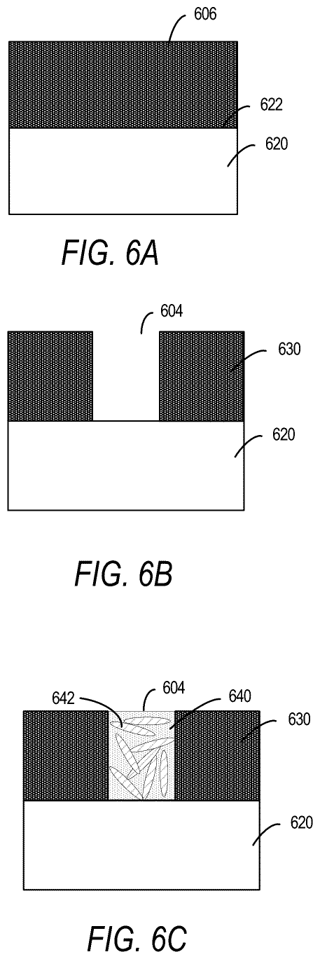

Elements 104 may include a compliant filler, discussed in more detail under FIG. 6C below. In one example, inclusion of a compliant filler will allow a degree of compression, thus allowing portions of the patterned layer 208 adjacent the elements 204 to expand and contract without causing warpage. The inclusion of a compliant filler further provides an advantage of keeping unwanted particle out of the elements 204 that may clog the elements 204 and reduce available expansion and contraction motion. One example of such a possibility includes a subsequent use of a thermal interface grease or other material that may include suspended particles. The inclusion of a compliant filler in elements 204 of pattern 206 facilitates use of a thermal interface grease while also keeping suspended particle from the thermal interface grease out of the elements 204 in the pattern 206.

In one example, a compliant filler within elements 204 of the pattern 206 further includes thermal conducting particles at a distribution that is effective at thermal conduction, but not so dense as to restrict thermal expansion and contraction adjacent to the elements 204. In such an example, the compliant filler may assist with thermal conduction but would be compliant enough to not add to the warpage of a die.

FIG. 3 shows a side view of a semiconductor device 300. The device 300 includes a die 310 and a patterned layer 308. The patterned layer 308 of FIG. 3 includes a pattern of elements 304 similar to pattern 206 of elements 204. In the example of FIG. 3, an intermediate layer 312 is included between the die 310 and the patterned layer 308.

In one embodiment, die 310 is connected to the patterned layer 308 through the intermediate layer 312. Although one intermediate layer 312 is shown, more than one intermediate layer may be included, provided heat is sufficiently able to conduct from the die 310 through to the patterned layer 308. In some embodiments, intermediate layer 312 may be optionally used between die 310 and patterned layer 308 for example, as a diffusion barrier or as a buffer layer. Intermediate layer 312 may be used in some embodiments to protect die 310 during the formation of elements 304, for example when elements 304 are formed using a die saw. Other methods where an intermediate layer 312 may provide protection include laser ablation, etching, etc.

Intermediate layer 312 may include titanium, nickel, vanadium, gold, or one or more combinations of these or other materials. Other thermal conducting materials are also within the scope of the invention. In one embodiment, a thickness of the intermediate layer 312 is between 10 nm and 500 nm.

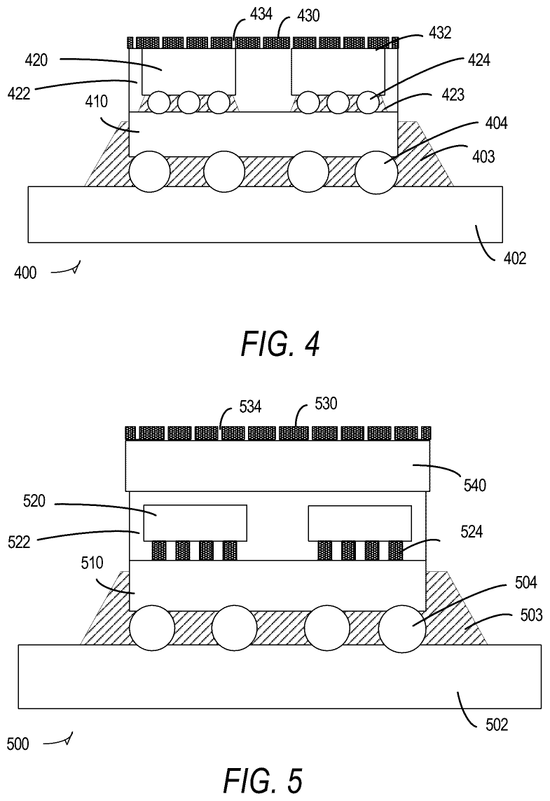

FIG. 4 illustrates one example of a semiconductor device 400 in accordance with some example embodiments. The device 400 of FIG. 4 includes a first die 410 coupled to a substrate 402. A first underfill 403 may be included around first solder connections 404, although the invention is not so limited. One or more secondary dies 420 are shown coupled to a top surface of the first die 410. A second underfill 423 may be included around second solder connections 424, although the invention is not so limited. In the example of FIG. 4, an encapsulant 422 is included, and at least partially covers the secondary dies 420. In the example of FIG. 4, the secondary dies 420 and encapsulant 422 form a level top surface 432 that facilitates formation of a patterned layer 430. In one example, the patterned layer 430 includes a pattern of elements 434 as described in other examples above. Inclusion of the pattern of elements 434 mitigates or eliminates warpage due to thermal expansion coefficient differences in materials while still providing thermal dissipation of heat from dies 410, 420, through the patterned layer 430.

In one example, patterned layer 430 may comprise thermally conductive material. Patterned layer 430 may further comprise a pattern of elements 434 that form recesses. The pattern of elements 434 may vary in size, shape, length, and width. In one embodiment, patterned layer 430 may consist of a pattern of elements 434 that form recesses with constant pitch in the X-Y direction. In another example, patterned layer 430 may consist of a thickness between 50 μm and 500 μm. The pattern of elements 434 may extend across an entire thickness of patterned layer 430.

FIG. 5 illustrates one example of a semiconductor device 500 in accordance with some example embodiments. The device 500 of FIG. 5 includes a first die 510 coupled to a substrate 502. A first underfill 503 may be included around first solder connections 504, although the invention is not so limited. One or more secondary dies 520 are shown coupled to a top surface of the first die 510. In the example of FIG. 5, the secondary dies 520 are coupled to a top surface of the first die 510 using a bonding technique such as a sold state reaction between materials to form a bond. In one example, the bond 524 includes an intermetallic, although the invention is not so limited. Other example configurations of bonding between secondary dies 520 and first dies 510 include solder connections.

In an embodiment, the connection of the first die 510 to secondary die(s) 520 may be made by use of a copper pad. In one embodiment, this connection, for example a copper pad, made be surrounded by an inorganic dielectric. For example, this inorganic dielectric may be silicon oxide or a combination of other similar materials.

In the example of FIG. 5, an encapsulant 522 is included, and at least partially covers the secondary dies 520. In the example of FIG. 5, the encapsulant 522 entirely covers a top surface of the secondary dies 520. The device 500 of FIG. 5 further includes a structural block 540. In one example, the structural block 540 includes silicon, although other materials are within the scope of the invention. The inclusion of the structural block 540 provides a level of mechanical strength to the device 500 to help resist any damage due to fragility of thin components. The example of FIG. 5 further includes a level top surface that facilitates formation of a patterned layer 530. In one example, the patterned layer 530 includes a pattern of elements 534 as described in other examples above. Inclusion of the pattern of elements 534 mitigates or eliminates warpage due to thermal expansion coefficient differences in materials while still providing thermal dissipation of heat from dies 510, 520, through the encapsulation 522 and structural block 540, and eventually through the patterned layer 530.

FIG. 6A illustrates a non-patterned thermal conducting structure of a semiconductor device in accordance with some example embodiments. As shown in FIG. 6A, an embodiment includes silicon structure 620 and thermal conducting layer 606. In FIG. 6A, the thermal conducting layer 606 forms a direct interface 622 with the silicon structure 620 although the invention is not so limited. As noted in examples above, an intermediate layer may be included between the silicon structure 620 and thermal conducting layer 606, provided there is still sufficient thermal conduction between the silicon structure 620 and the thermal conducting layer 606. In one example, the silicon structure 620 includes a die. In one example, the silicon structure 620 includes a structural block, such as structural block 540 from FIG. 5.

FIG. 6B shows a formation of an element 604 in pattern of elements. The element 604 forms a recess in the thermal conducting layer 606 of FIG. 6A to form patterned layer 630. In some embodiments, element 604 may extend across an entire thickness of patterned layer 630, as depicted. However, in some embodiments, element 604 may extend across only a portion of the thickness of patterned layer 630. As noted in examples above, a pattern of elements 604 may be formed with variations across a surface of the thermal conducting layer 606 to form a patterned layer.

FIG. 6C illustrates the patterned layer 630 from FIG. 6B. The example of FIG. 6C includes a compliant filler 640 within the element 604. The compliant filler 640 may include thermally conductive particles 642. Examples of thermally conductive particles 642 include, but are not limited to, zinc oxide nanoparticles, copper nanoparticles, nanodiamond, graphene, or silver nanoparticles. Although nanoparticles indicate an advantageous size scale, other sizes of particles 642 that fit into the element 604 are also within the scope of the invention. Element 604 may comprise compliant filler 640 to assist with thermal conduction. In the example shown, the compliant filler 640 includes a matrix material and may also include conductive particles 642 as noted above. Examples of matrix materials include, but are not limited to, polymer materials. One example polymer material includes silicone, although the invention is not so limited. A solid, but flexible compliant material includes an advantage over a grease or oil material, in that it resists collection of unwanted particles that may get caught within the element 604, while still maintaining enough compliance to allow expansion and contraction of the patterned layer 630 to resists warpage.

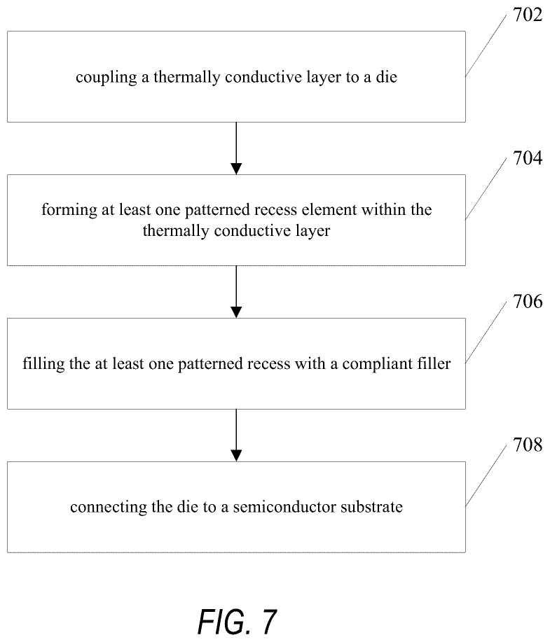

FIG. 7 shows an example flow diagram of a method of manufacturing a semiconductor device. In operation 702, a thermally conductive layer is coupled to a die. In operation 704, at least one patterned recess element is formed within the thermally conductive layer. In operation 706, the at least one patterned recess is filled with a compliant filler, and in operation 708 the die is connected to a semiconductor substrate.

In one example, devices as described in the present disclosure have reduced warpage, especially during fluctuations in temperature. One advantage of reduced warpage includes more reliable die testing. After manufacture, dies are often tested to be sure that they are functioning as desired. By detecting defective dies early, bad dies can be discarded before being incorporated into higher level devices such as the system 800 described below. This can provide a significant cost savings, because if a bad die is discovered later in manufacturing, a more expensive system may need to be scrapped, as compared to the die by itself.

During one example of die testing, a die is probed, and exposed to different temperature environments to stress the die and evaluate how robust the die is when subjected to temperature variations. Warpage during die probing may cause a good die to fail, only because probes fail to make contact with the die, not because the die itself is bad. By reducing warpage at a die level, a probing operation reliability is improved.

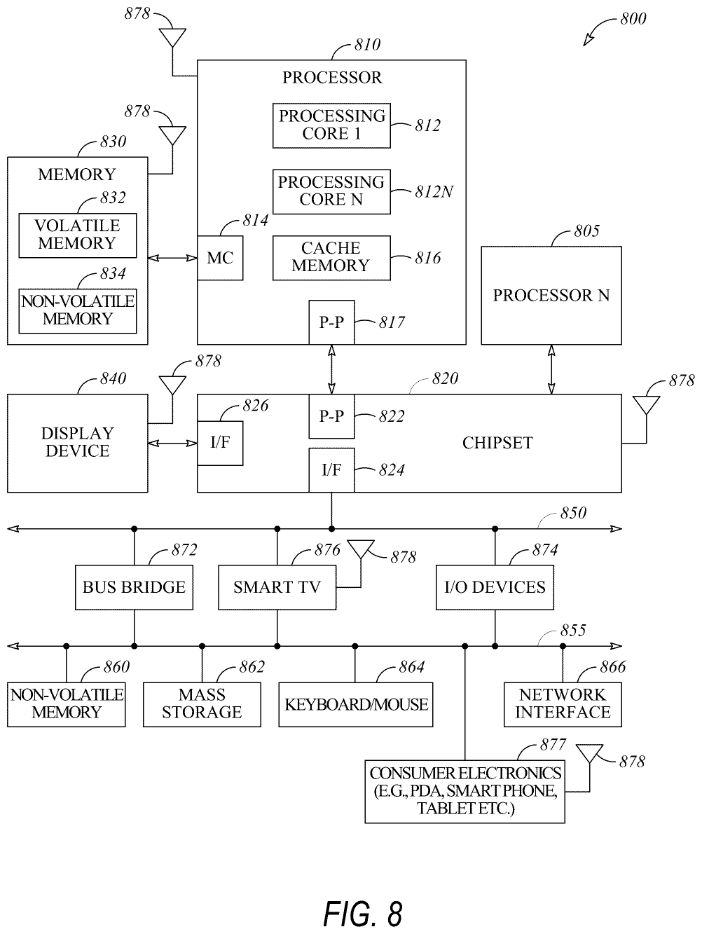

FIG. 8 illustrates a system level diagram, depicting an example of an electronic device (e.g., system) that may include a patterned layer and methods described above. In one embodiment, system 800 includes, but is not limited to, a desktop computer, a laptop computer, a netbook, a tablet, a notebook computer, a personal digital assistant (PDA), a server, a workstation, a cellular telephone, a mobile computing device, a smart phone, an Internet appliance or any other type of computing device. In some embodiments, system 800 includes a system on a chip (SOC) system.

In one embodiment, processor 810 has one or more processor cores 812 and 812N, where 812N represents the Nth processor core inside processor 810 where N is a positive integer. In one embodiment, system 800 includes multiple processors including 810 and 805, where processor 805 has logic similar or identical to the logic of processor 810. In some embodiments, processing core 812 includes, but is not limited to, pre-fetch logic to fetch instructions, decode logic to decode the instructions, execution logic to execute instructions and the like. In some embodiments, processor 810 has a cache memory 816 to cache instructions and/or data for system 800. Cache memory 816 may be organized into a hierarchal structure including one or more levels of cache memory.

In some embodiments, processor 810 includes a memory controller 814, which is operable to perform functions that enable the processor 810 to access and communicate with memory 830 that includes a volatile memory 832 and/or a non-volatile memory 834. In some embodiments, processor 810 is coupled with memory 830 and chipset 820. Processor 810 may also be coupled to a wireless antenna 878 to communicate with any device configured to transmit and/or receive wireless signals. In one embodiment, an interface for wireless antenna 878 operates in accordance with, but is not limited to, the IEEE 802.11 standard and its related family, Home Plug AV (HPAV), Ultra Wide Band (UWB), Bluetooth, WiMax, or any form of wireless communication protocol.

In some embodiments, volatile memory 832 includes, but is not limited to, Synchronous Dynamic Random Access Memory (SDRAM), Dynamic Random Access Memory (DRAM), RAMBUS Dynamic Random Access Memory (RDRAM), and/or any other type of random access memory device. Non-volatile memory 834 includes, but is not limited to, flash memory, phase change memory (PCM), read-only memory (ROM), electrically erasable programmable read-only memory (EEPROM), or any other type of non-volatile memory device.

Memory 830 stores information and instructions to be executed by processor 810. In one embodiment, memory 830 may also store temporary variables or other intermediate information while processor 810 is executing instructions. In the illustrated embodiment, chipset 820 connects with processor 810 via Point-to-Point (PtP or P-P) interfaces 817 and 822. Chipset 820 enables processor 810 to connect to other elements in system 800. In some embodiments of the example system, interfaces 817 and 822 operate in accordance with a PtP communication protocol such as the Intel® QuickPath Interconnect (QPI) or the like. In other embodiments, a different interconnect may be used.

In some embodiments, chipset 820 is operable to communicate with processor 810, 805N, display device 840, and other devices, including a bus bridge 872, a smart TV 876, I/O devices 874, nonvolatile memory 860, a storage medium (such as one or more mass storage devices) 862, a keyboard/mouse 864, a network interface 866, and various forms of consumer electronics 877 (such as a PDA, smart phone, tablet etc.), etc. In one embodiment, chipset 820 couples with these devices through an interface 824. Chipset 820 may also be coupled to a wireless antenna 878 to communicate with any device configured to transmit and/or receive wireless signals. In one example, any combination of components in a chipset may be separated by a continuous flexible shield as described in the present disclosure.

Chipset 820 connects to display device 840 via interface 826. Display 840 may be, for example, a liquid crystal display (LCD), a light emitting diode (LED) array, an organic light emitting diode (OLED) array, or any other form of visual display device. In some embodiments of the example system, processor 810 and chipset 820 are merged into a single SOC. In addition, chipset 820 connects to one or more buses 850 and 855 that interconnect various system elements, such as I/O devices 874, nonvolatile memory 860, storage medium 862, a keyboard/mouse 864, and network interface 866. Buses 850 and 855 may be interconnected together via a bus bridge 872.

In one embodiment, mass storage device 862 includes, but is not limited to, a solid state drive, a hard disk drive, a universal serial bus flash memory drive, or any other form of computer data storage medium. In one embodiment, network interface 866 is implemented by any type of well-known network interface standard including, but not limited to, an Ethernet interface, a universal serial bus (USB) interface, a Peripheral Component Interconnect (PCI) Express interface, a wireless interface and/or any other suitable type of interface. In one embodiment, the wireless interface operates in accordance with, but is not limited to, the IEEE 802.11 standard and its related family, Home Plug AV (HPAV), Ultra Wide Band (UWB), Bluetooth, WiMax, or any form of wireless communication protocol.

While the modules shown in FIG. 8 are depicted as separate blocks within the system 800, the functions performed by some of these blocks may be integrated within a single semiconductor circuit or may be implemented using two or more separate integrated circuits. For example, although cache memory 816 is depicted as a separate block within processor 810, cache memory 816 (or selected aspects of 816) can be incorporated into processor core 812.

To better illustrate the method and apparatuses disclosed herein, a non-limiting list of embodiments is provided here:

Example 1 includes a semiconductor device. The semiconductor device includes a semiconductor substrate, a die connected to the semiconductor substrate, and a patterned layer connected to a backside of the die. The patterned layer comprises a thermally conductive material. The patterned layer comprises a pattern of elements that form recesses, wherein the pattern of elements varies across the backside of the die.

Example 2 includes the semiconductor device of example 1, further comprising at least one thermally conducting middle layer between the die and the patterned layer.

Example 3 includes the semiconductor device of any one of examples 1-2, wherein the thermally conductive material includes a metal.

Example 4 includes the semiconductor of any one of examples 1-3, wherein the metal includes copper.

Example 5 includes the semiconductor device of any one of examples 1-4, wherein the thermally conductive material includes diamond.

Example 6 includes the semiconductor device of any one of examples 1-5, wherein an element in the pattern of elements extends across an entire width of the die.

Example 7 includes the semiconductor device of any one of examples 1-6, wherein an element in the pattern of elements includes an arced geometry.

Example 8 includes the semiconductor device of any one of examples 1-7, wherein the recesses include a compliant filler.

Example 9 includes the semiconductor device of any one of examples 1-8, wherein the compliant filler includes thermally conductive particles.

Example 10 includes the semiconductor device of any one of examples 1-9, wherein a thickness of the patterned layer is between 50 μm and 500 μm.

Example 11 is a semiconductor device. The semiconductor device includes a semiconductor substrate and a base die connected to the semiconductor substrate wherein one or more secondary dies is coupled to a backside of the base die. The semiconductor device includes a patterned layer connected to a backside of the semiconductor device. The patterned layer comprises a thermally conductive material. The patterned layer comprises a pattern of elements that form recesses, wherein the pattern of elements varies across the backside of the semiconductor device.

Example 12 includes the semiconductor device of example 11, wherein the patterned layer forms a direct interface with the one or more secondary dies.

Example 13 includes the semiconductor device of any one of examples 11-12, further including a silicon structure over the one or more secondary dies, wherein the patterned layer forms a direct interface with the silicon structure.

Example 14 includes the semiconductor device of any one of examples 11-13, wherein the dielectric material includes a polymeric mold material.

Example 15 includes the semiconductor device of any one of examples 11-14, wherein the dielectric material includes silicon oxide glass.

Example 16 includes the semiconductor device of any one of examples 11-15, wherein the recesses include a compliant filler.

Example 17 includes the semiconductor device of any one of examples 11-16, wherein the compliant filler includes thermally conductive particles.

Example 18 is a method of manufacturing a semiconductor device. The method includes coupling a thermally conductive layer to a die, forming at least one patterned recess element within the thermally conductive layer, filling the at least one patterned recess with a compliant filler, and connecting the die to a semiconductor substrate.

Example 19 includes the method of example 18, wherein forming at least one patterned recess element includes laser ablation.

Example 20 includes the method of any one of examples 18-19, further including probing the die to test for manufacturing defects prior to connecting the die to the semiconductor substrate.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

Although an overview of the inventive subject matter has been described with reference to specific example embodiments, various modifications and changes may be made to these embodiments without departing from the broader scope of embodiments of the present disclosure. Such embodiments of the inventive subject matter may be referred to herein, individually or collectively, by the term “invention” merely for convenience and without intending to voluntarily limit the scope of this application to any single disclosure or inventive concept if more than one is, in fact, disclosed.

The embodiments illustrated herein are described in sufficient detail to enable those skilled in the art to practice the teachings disclosed. Other embodiments may be used and derived therefrom, such that structural and logical substitutions and changes may be made without departing from the scope of this disclosure. The Detailed Description, therefore, is not to be taken in a limiting sense, and the scope of various embodiments is defined only by the appended claims, along with the full range of equivalents to which such claims are entitled.

As used herein, the term “or” may be construed in either an inclusive or exclusive sense. Moreover, plural instances may be provided for resources, operations, or structures described herein as a single instance. Additionally, boundaries between various resources, operations, modules, engines, and data stores are somewhat arbitrary, and particular operations are illustrated in a context of specific illustrative configurations. Other allocations of functionality are envisioned and may fall within a scope of various embodiments of the present disclosure. In general, structures and functionality presented as separate resources in the example configurations may be implemented as a combined structure or resource. Similarly, structures and functionality presented as a single resource may be implemented as separate resources. These and other variations, modifications, additions, and improvements fall within a scope of embodiments of the present disclosure as represented by the appended claims. The specification and drawings are, accordingly, to be regarded in an illustrative rather than a restrictive sense.

The foregoing description, for the purpose of explanation, has been described with reference to specific example embodiments. However, the illustrative discussions above are not intended to be exhaustive or to limit the possible example embodiments to the precise forms disclosed. Many modifications and variations are possible in view of the above teachings. The example embodiments were chosen and described in order to best explain the principles involved and their practical applications, to thereby enable others skilled in the art to best utilize the various example embodiments with various modifications as are suited to the particular use contemplated.

It will also be understood that, although the terms “first,” “second,” and so forth may be used herein to describe various elements, these elements should not be limited by these terms. These terms are only used to distinguish one element from another. For example, a first contact could be termed a second contact, and, similarly, a second contact could be termed a first contact, without departing from the scope of the present example embodiments. The first contact and the second contact are both contacts, but they are not the same contact.

The terminology used in the description of the example embodiments herein is for the purpose of describing particular example embodiments only and is not intended to be limiting. As used in the description of the example embodiments and the appended examples, the singular forms “a,” “an,” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

As used herein, the term “if” may be construed to mean “when” or “upon” or “in response to determining” or “in response to detecting,” depending on the context. Similarly, the phrase “if it is determined” or “if [a stated condition or event] is detected” may be construed to mean “upon determining” or “in response to determining” or “upon detecting [the stated condition or event]” or “in response to detecting [the stated condition or event],” depending on the context.

1. A semiconductor device, comprising:
a semiconductor substrate;
a die connected to the semiconductor substrate; and
a patterned layer connected to a backside of the die, comprised of thermally conductive material, wherein the patterned layer comprises a pattern of elements that form recesses, wherein the pattern of elements varies across the backside of the die.

2. The semiconductor device of claim 1, further comprising at least one thermally conducting middle layer between the die and the patterned layer.

3. The semiconductor device of claim 1, wherein the thermally conductive material includes a metal.

4. The semiconductor device of claim 3, wherein the metal includes copper.

5. The semiconductor device of claim 1, wherein the thermally conductive material includes diamond.

6. The semiconductor device of claim 1, wherein an element in the pattern of elements extends across an entire width of the die.

7. The semiconductor device of claim 1, wherein an element in the pattern of elements includes an arced geometry.

8. The semiconductor device of claim 1, wherein the recesses include a compliant filler.

9. The semiconductor device of claim 8, wherein the compliant filler includes thermally conductive particles.

10. The semiconductor device of claim 1, wherein a thickness of the patterned layer is between 50 μm and 500 μm.

11. A semiconductor device, comprising:
a semiconductor substrate;
a base die connected to the semiconductor substrate;
one or more secondary dies coupled to a backside of the base die;
a dielectric material encapsulating the one or more secondary dies; and
a patterned layer connected to a backside of the semiconductor device, the patterned layer comprised of thermally conductive material, wherein the patterned layer comprises a pattern of elements that form recesses, wherein the pattern of elements varies across the backside of the semiconductor device.

12. The semiconductor device of claim 11, wherein the patterned layer forms a direct interface with the one or more secondary dies.

13. The semiconductor device of claim 11, further including a silicon structure over the one or more secondary dies, wherein the patterned layer forms a direct interface with the silicon structure.

14. The semiconductor device of claim 11, wherein the dielectric material includes a polymeric mold material.

15. The semiconductor device of claim 11, wherein the dielectric material includes silicon oxide glass.

16. The semiconductor device of claim 11, wherein the recesses include a compliant filler.

17. The semiconductor device of claim 16, wherein the compliant filler includes thermally conductive particles.

18. A method of manufacturing a semiconductor device, comprising:
coupling a thermally conductive layer to a die;
forming at least one patterned recess element within the thermally conductive layer;
filling the at least one patterned recess with a compliant filler; and
connecting the die to a semiconductor substrate.

19. The method of claim 18, wherein forming at least one patterned recess element includes laser ablation.

20. The method of claim 18, further including probing the die to test for manufacturing defects prior to connecting the die to the semiconductor substrate.
